(19) United States
(12) Patent Application Publication
(10) Pub. No.: US 2014/0015767 A1
(43) Pub. Date: Jan. 16, 2014

(54) TOUCH PANEL AND MANUFACTURING METHOD THEREOF AND TOUCH DISPLAY PANEL

(71) Applicants: Yun-Nan Hsieh, Hsinchu (TW); Lin-An Chen, Hsinchu (TW)

(72) Inventors: Yun-Nan Hsieh, Hsinchu (TW); Lin-An Chen, Hsinchu (TW)

(73) Assignee: E INK HOLDINGS INC., Hsinchu (TW)

(21) Appl. No.: 13/620,727

(22) Filed: Sep. 15, 2012

(30) Foreign Application Priority Data
Jul. 10, 2012 (TW) 101124812

(51) Int. Cl. G06F 3/041; H05K 13/00

(52) U.S. Cl. 345/173; 29/622

(57) ABSTRACT

A touch panel including a first and a second substrates, a first and a second sensing electrode layers, plural first lines, plural second lines, a conductive material layer and a shielding layer is provided. The first and the second sensing electrode layers are respectively disposed on the first and the second substrates and located in a sensing region. The first and the second lines are disposed on the first substrate and located in a periphery region. The first lines connect to the first sensing electrode layer. The optical adhesive layer encapsulates the first and the second sensing electrode layers and the first and the second lines. The optical adhesive layer has an opening. The conductive material layer is disposed inside the opening. The second lines connect to the second sensing electrode layer via the conductive material layer. The shielding layer is located above the first and the second lines.

### CROSS-REFERENCE TO RELATED APPLICATION

This application claims the priority benefit of Taiwan application serial no. 101124812, filed on Jul. 10, 2012. the entirety of the above-mentioned patent application is hereby incorporated by reference herein and made a part of this specification.

### BACKGROUND

1. Technical Field

The invention relates to a touch panel and a manufacturing method thereof. Particularly, the invention relates to a touch panel and a manufacturing method thereof and a touch display panel.

2. Related Art

Along with booming development of electronic technology, and popularisation of wireless communications and networking, various electronic devices gradually become indispensable tools in daily life. However, a commonly used input/output (I/O) interface, such as a keyboard or a mouse has a certain degree of operation difficulty. Comparatively, a touch panel is an intuitive and simple I/O interface. Therefore, the touch panel is generally used as a communication interface between human and the electronic device for control implementation.

The current products are continuously developed in a trend of integrating a touch panel with a display panel to form a touch display panel. Regarding manufacturing of the commonly used touch display panel, the touch panel and the display panel are separately manufactured, and then the touch panel is adhered to the display panel. The touch panel is approximately grouped into resistive, capacitive, infrared and ultrasonic touch panels, in which the resistive touch panels and the capacitive touch panels are most commonly used products.

Regarding the capacitive touch panel, a sensing region in the touch panel includes a plurality of sensing series of an X-direction and a plurality of sensing series of a Y-direction, and a periphery region of the touch panel includes a plurality of metal lines respectively connected to the sensing series of the X-direction and the sensing series of the Y-direction. Regarding manufacturing of the conventional touch panel, the sensing series of the X-direction and the metal lines connected to the sensing series of the X-direction are formed on a substrate through two masks or printing, and the sensing series of the Y-direction and the metal lines connected to the sensing series of the Y-direction are formed on another substrate through two masks or printing. If a photolithography process is used to form the metal lines and the sensing series of the X-direction and the Y-direction through masks, at least four masks are used, which is rather complicated and has a low production yield. If a printing process is used to form the metal lines and the sensing series of the X-direction and the Y-direction, although it has simple manufacturing steps, a line width of the formed metal line is relatively large, which is, for example, at least between 50 μm and 100 μm, and a narrow line width effect cannot be achieved.

### SUMMARY

The invention is directed to a touch panel, in which lines in a periphery region have a smaller line width and pitch, which achieves a narrow line width effect.

The invention is directed to a manufacturing method of a touch panel, which is used to manufacture the aforementioned touch panel, and has a higher production yield and lower production cost.

The invention is directed to a touch display panel, which has a design of a narrow line width.

An embodiment of the invention provides a touch panel having a sensing region and a periphery region surrounding the sensing region. The touch panel includes a first substrate, a second substrate, a first sensing electrode layer, a second sensing electrode layer, a plurality of first lines, a plurality of second lines, an optical adhesive layer, a conductive material layer and a shielding layer. The second substrate is disposed opposite to the first substrate. The first sensing electrode layer is disposed on the first substrate and is located in the sensing region, where a portion of the first sensing electrode layer extends to the periphery region. The second sensing electrode layer is disposed on the second substrate and faces to the first sensing electrode layer. The second sensing electrode layer is located in the sensing region, where a portion of the second sensing electrode layer extends to the periphery region. The first lines are disposed on the first substrate and located in the peripheral region. The first lines are electrically insulated to each other, and are connected to the first sensing electrode layer. The second lines are disposed on the first substrate and located in the peripheral region, where the second lines are electrically insulated to each other. The optical adhesive layer is disposed between the first substrate and the second substrate, and encapsulates the first sensing electrode layer, the second sensing electrode layer, the first lines and the second lines. The optical adhesive layer has at least one opening exposing the portion of the second sensing electrode layer extending to the periphery region. The conductive material layer is disposed inside the opening of the optical adhesive layer. The second lines are connected to the second sensing electrode layer through the conductive material layer. The shielding layer is disposed between the first substrate and the second substrate, and located in the periphery region above the first and the second lines.

An embodiment of the invention provides a manufacturing method of a touch panel, which includes following steps. A first substrate is provided, where the first substrate has a first central region and a first periphery region surrounding the first central region. A first sensing electrode layer is formed in the first central region of the first substrate, where a portion of the first sensing electrode layer extends to the first periphery region. A plurality of first lines and a plurality of second lines are formed in the first periphery region of the first substrate, where the first lines are electrically insulated to each other, and the second lines are electrically insulated to each other, and the first lines are connected to the first sensing electrode layer. A second substrate is provided, where the second substrate has a second central region and a second periphery region surrounding the second central region. A second sensing electrode layer is formed in the second central region of the second substrate, and faces to the first sensing electrode layer, where a portion of the second sensing electrode layer extends to the second periphery region. An optical adhesive layer is formed in the second central region and the second periphery region of the second substrate. The optical adhesive layer covers the second sensing electrode layer and has at least one opening, where the opening exposes the portion of the second sensing electrode layer. A conductive material layer is filled in the opening of the optical adhesive layer, where the conductive material layer is connected to the portion of second sensing electrode layer exposed by the opening. An adhesion process is performed on the first substrate and the second substrate to fix the second substrate to the first substrate through the optical adhesive layer. The first sensing electrode layer faces to the second sensing electrode layer, and the optical adhesive layer encapsulates the first sensing electrode layer, the second sensing electrode layer, the first lines, the second lines and the conductive material layer. The second lines are connected to the portion of second sensing electrode layer exposed by the opening through the conductive material layer. Before the adhesion process is performed, a shielding layer is formed in the first periphery region of the first substrate or in the second periphery region of the second substrate, where the shielding layer is located above the first and the second lines.

An embodiment of the invention provides a touch display panel including a touch panel and a display panel. The touch panel has a sensing region and a periphery region surrounding the sensing region, and includes a first substrate, a second substrate, a first sensing electrode layer, a second sensing electrode layer, a plurality of first lines, a plurality of second lines, an optical adhesive layer, a conductive material layer and a shielding layer. The second substrate is disposed opposite to the first substrate. The first sensing electrode layer is disposed on the first substrate and is located in the sensing region, where a portion of the first sensing electrode layer extends to the periphery region. The second sensing electrode layer is disposed on the second substrate and faces to the first sensing electrode layer. The second sensing electrode layer is located in the sensing region, where a portion of the second sensing electrode layer extends to the periphery region. The first lines are disposed on the first substrate and located in the peripheral region. The first lines are electrically insulated to each other, and are connected to the first sensing electrode layer. The second lines are disposed on the first substrate and located in the peripheral region, where the second lines are electrically insulated to each other. The optical adhesive layer is disposed between the first substrate and the second substrate, and encapsulates the first sensing electrode layer, the second sensing electrode layer, the first lines and the second lines. The optical adhesive layer has at least one opening exposing a portion of the second sensing electrode layer extending to the periphery region. The conductive material layer is disposed inside the opening of the optical adhesive layer. The second lines are connected to the second sensing electrode layer through the conductive material layer. The shielding layer is disposed between the first substrate and the second substrate, and located in the periphery region above the first and the second lines. The display panel is disposed under the touch panel.

According to the above descriptions, since the first lines and the second lines of the touch panel of the embodiments of the invention are all disposed on the first substrate, manufacturing of the first lines and the second lines can be completed through a same manufacturing process, which may effectively reduce manufacturing steps and improve production yield.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top view of a first substrate of a touch panel according to an embodiment of the invention.

FIG. 1B is a top view of a second substrate corresponding to the first substrate of the touch panel of FIG. 1A.

FIG. 1C is a cross-sectional view of FIG. 1A and FIG. 1B along an I-I line.

FIGS. 2A-2H are cross-sectional views of a manufacturing method of a touch panel according to an embodiment of the invention.

FIG. 3 is a cross-sectional view of a touch display panel according to an embodiment of the invention.

### DETAILED DESCRIPTION OF DISCLOSED EMBODIMENTS

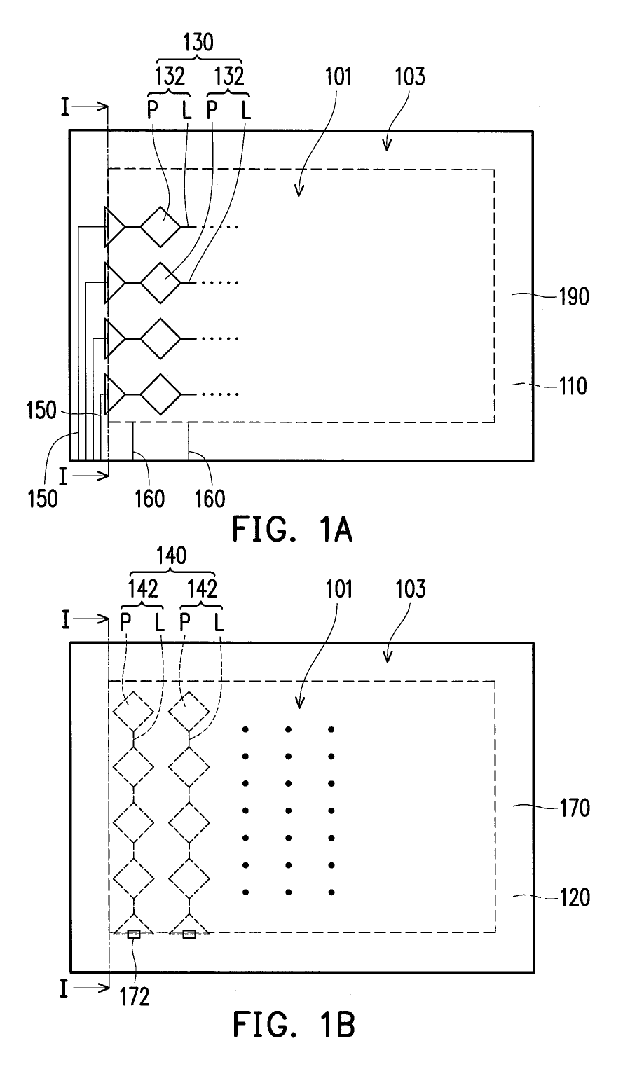

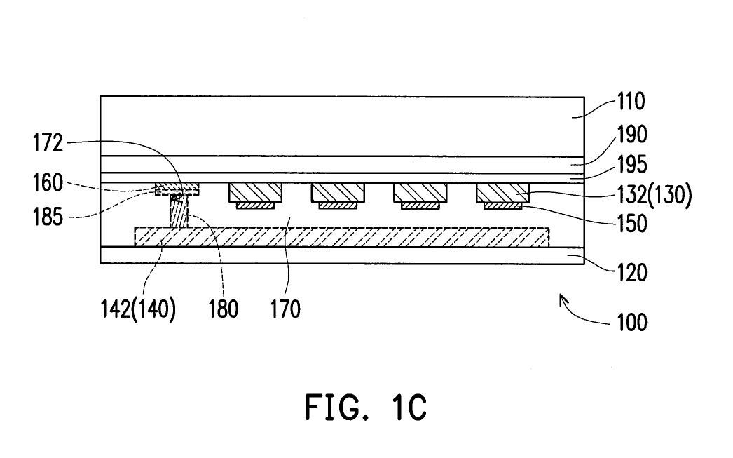

FIG. 1A is a top view of a first substrate of a touch panel according to an embodiment of the invention. FIG. 1B is a top view of a second substrate corresponding to the first substrate of the touch panel of FIG. 1A. FIG. 1C is a cross-sectional view of FIG. 1A and FIG. 1B along an I-I line. For simplicity's sake, a part of members are omitted in FIG. 1A and FIG. 1B. Referring to FIG. 1A, FIG. 1B and FIG. 1C, in the present embodiment, the touch panel 100 has a sensing region 101 and a periphery region 103 surrounding the sensing region 101. The touch panel 100 includes a first substrate 110, a second substrate 120, a first sensing electrode layer 130, a second sensing electrode layer 140, a plurality of first lines 150, a plurality of second lines 160, an optical adhesive layer 170, a conductive material layer 180 and a shielding layer 190.

In detail, the second substrate 120 is disposed opposite to the first substrate 110. The first sensing electrode layer 130 is disposed on the first substrate 110 and is located in the sensing region 101, where a portion of the first sensing electrode layer 130 extends to the periphery region 103. The second sensing electrode layer 140 is disposed on the second substrate 120 and faces to the first sensing electrode layer 130. The second sensing electrode layer 140 is located in the sensing region 101, where a portion of the second sensing electrode layer 140 extends to the periphery region 103. The first lines 150 are disposed on the first substrate 110 and located in the peripheral region 103. The first lines 150 are electrically insulated to each other, and are structurally and electrically connected to the first sensing electrode layer 130. The second lines 160 are disposed on the first substrate 110 and located in the peripheral region 103, where the second lines 160 are electrically insulated to each other. The optical adhesive layer 170 is disposed between the first substrate 110 and the second substrate 120, and encapsulates the first sensing electrode layer 130, the second sensing electrode layer 140, the first lines 150 and the second lines 160. The optical adhesive layer 170 has at least one opening 172 exposing a portion of the second sensing electrode layer 140 extending to the periphery region 103. The conductive material layer 180 is disposed inside the opening 172 of the optical adhesive layer 170, where the second lines 160 are connected to the second sensing electrode layer 140 through the conductive material layer 180. The shielding layer 190 is disposed between the first substrate 110 and the second substrate 120, and is located in the periphery region 103 above the first lines 150 and the second lines 160.

In detail, in the present embodiment, the first substrate 110 can be regarded as an upper substrate, and the second substrate 120 can be regarded as a lower substrate, where the first substrate 110 is a rigid substrate, which is, for example, a glass substrate, and the second substrate 120 is a flexible thin film, which is, for example, a polyethylene terephthalate (PET) thin film. Namely, the first sensing electrode layer 130, the first lines 150 and the second lines 160 of the present embodiment are all disposed on the rigid substrate (i.e. the upper substrate), and the second sensing electrode layer 140 is disposed on the flexible thin film (i.e. the lower substrate). However, configurations and materials of the first substrate 110 and the second substrate 120 are not limited by the invention, and in other embodiments that are not illustrated, the second substrate 120 can be regarded as the upper substrate, and the first substrate 110 can be regarded as the lower substrate, where the second substrate 120 is a rigid substrate, and the first substrate 110 is a flexible thin film. Namely, the first sensing electrode layer 130, the first lines 150 and the second lines 160 are all disposed on the flexible thin film (i.e. the lower substrate), and the second sensing electrode layer 140 is disposed on the rigid substrate (i.e. the upper substrate), which is also a technical solution without departing from a protection range of the invention.

Moreover, as shown in FIG. 1A and FIG. 1B, the first sensing electrode layer 130 of the present embodiment is composed of a plurality of first sensing series 132 extending along a horizontal direction, and the second sensing electrode layer 140 is composed of a plurality of second sensing series 142 extending along a vertical direction. The first sensing series 132 and the second sensing series 142 are all illustrated as structures in which a plurality of bridge lines L connect a plurality of diamond touch pads P in series, and in the present embodiment, the bridge lines L and the diamond touch pads P can be formed integrally. However, in other embodiments that are not illustrated, the shape of the touch pad can be a rectangle, a circle, a triangle or other shapes, and whether the bridge lines are used is not limited by the invention. Moreover, a material of the first sensing electrode layer 130 and a material of the second sensing electrode layer 140 is, for example, indium tin oxide (ITO) or indium zinc oxide (IZO). The first lines 150 and the second lines 160 are all disposed on the first substrate 110, and a material of the first lens 160 and the second lines 160 is, for example, metal. A material of the conductive material layer 180 is, for example, silver, which is used to electrically connect the second lines 160 on the first substrate 110 to the second sensing electrode layer 140 on the second substrate 120. Moreover, the shielding layer 190 is, for example, a black matrix layer, and is used to shield the first lines 150 and the second lines 160 in the periphery region 103, so that the shielding layer 190 is required to be configured between a user (not shown) and the first lines 150 and between the user (not shown) and the second lines 160. Here, as shown in FIG. 1C, the shielding layer 190 is disposed between the first substrate 110 and the first sensing electrode layer 130. In case that the shielding layer 190 is configured, a light shielding effect of the periphery region 103 is improved.

Moreover, referring to FIG. 1C, in order to blur a pattern of the first sensing electrode layer 130, the touch panel 100 may further include an optical layer 195, which is disposed on the shielding layer 190 and located between the first substrate 110 and the first sensing electrode layer 130. In detail, the optical layer 195 is located between the shielding layer 190 and the first sensing electrode layer 130, and covers the first sensing electrode layer 130. In other embodiments, if the second substrate is located between the user (not shown) and the first substrate 110, the optical layer 195 is located between the second substrate 120 and the second sensing electrode layer 140. Moreover, in order to improve electrical reliability between the second lines 160 and the second sensing electrode layer 140, the touch panel 100 of the present embodiment further includes an anisotropic conductive adhesive layer 185, which is disposed on the second lines 160, where the second lines 160 are structurally and electrically connected to the second sensing electrode layer 140 through the conductive material layer 180 and the anisotropic conductive adhesive layer 185. In brief, the anisotropic conductive adhesive layer 185 is a selective member. Namely, in other embodiments that are not illustrated, the touch panel does not include the anisotropic conductive adhesive layer 185, which is also a technical solution without departing from a protection range of the invention.

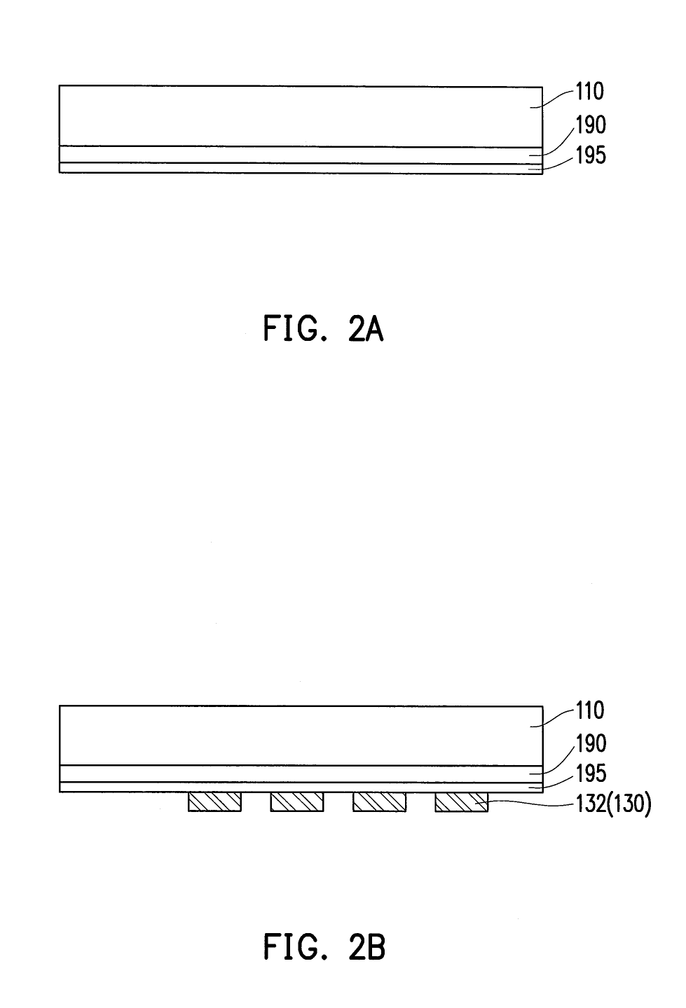

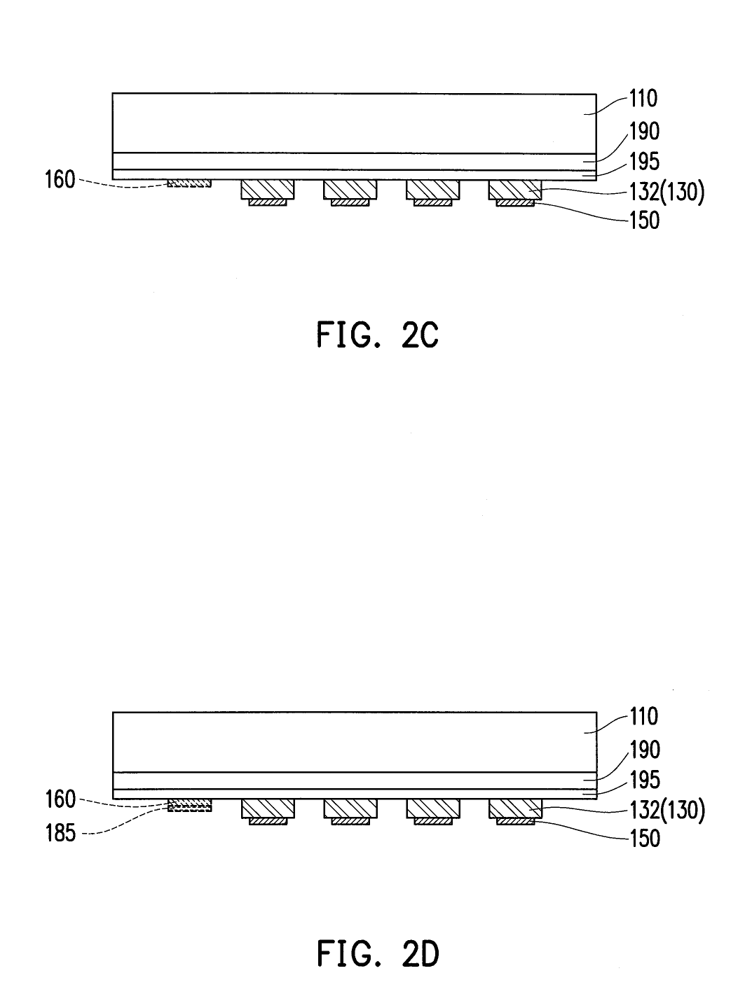

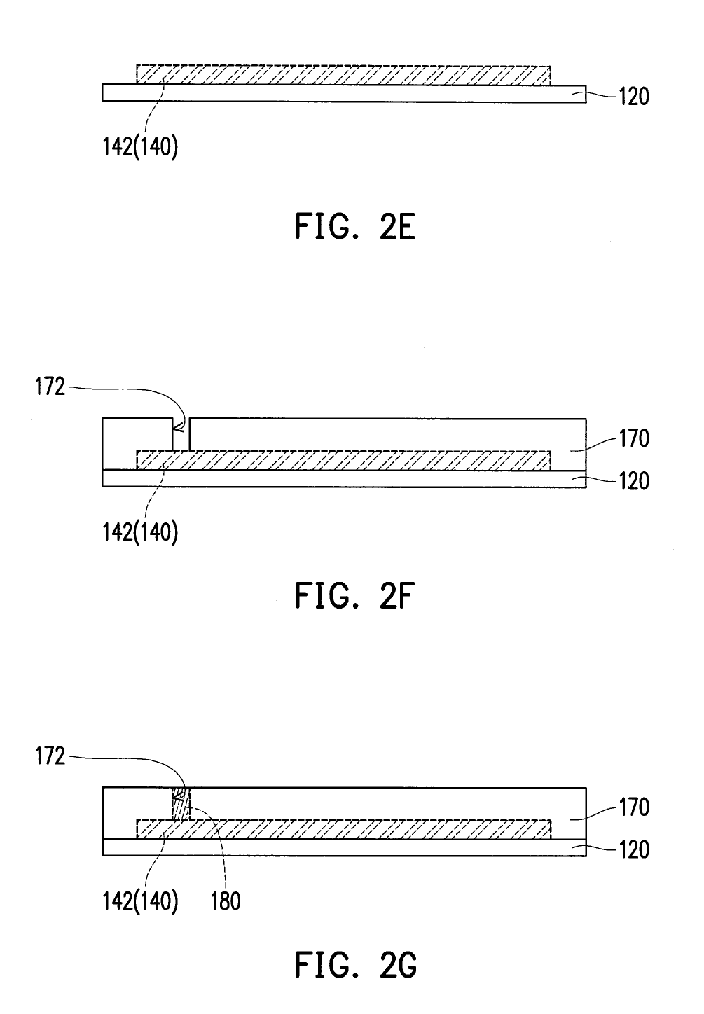

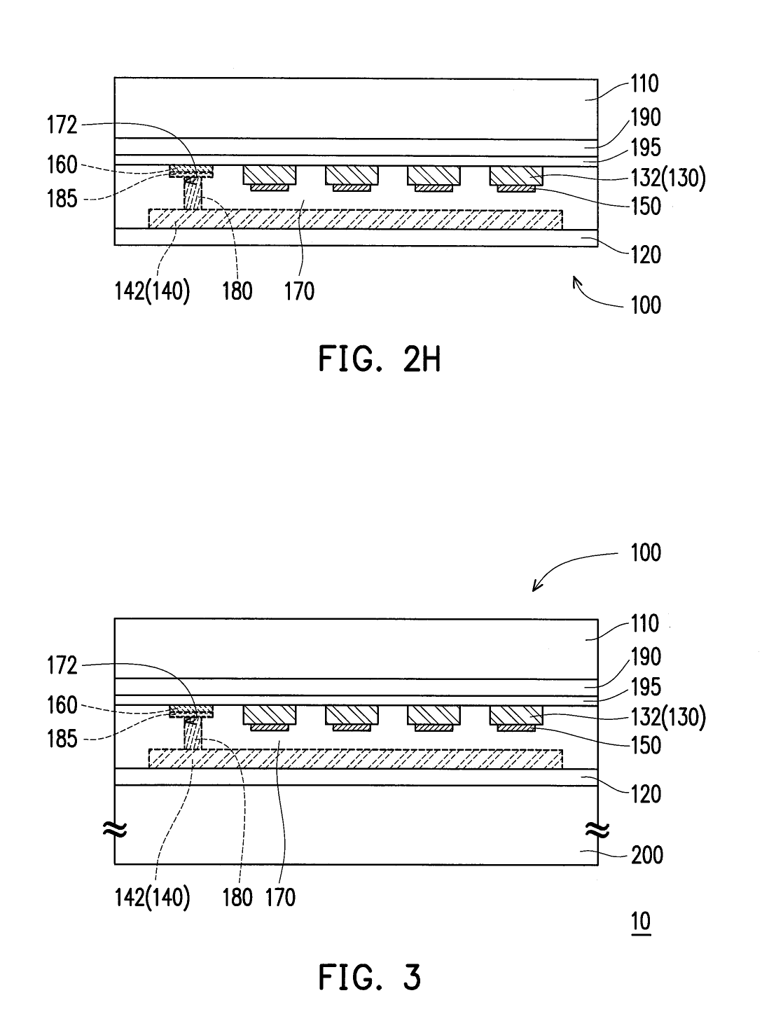

The structure of the touch panel 100 of an embodiment of the invention is introduced above, and a manufacturing method thereof is not introduced. Therefore, an embodiment is provided below to introduce the manufacturing method of the touch panel 100, and the manufacturing method of the touch panel 100 is described in detail with reference of FIG. 1A, FIG. 1B and FIGS. 2A-2H.

FIGS. 2A-2H are cross-sectional views of a manufacturing method of a touch panel according to an embodiment of the invention. Referring to FIG. 1A and FIG. 2A, in the manufacturing method of the touch panel 100, first, a first substrate 110 is provided, where the first substrate 110 has a first central region (i.e. the sensing region 101 of FIG. 1A) and a first periphery region (i.e. the periphery region 103 of FIG. 1A) surrounding the first central region.

Then, referring to FIG. 2A, a shielding layer 190 is formed on the first substrate 110 and is located in the first periphery region (i.e. the periphery region 103 of FIG. 1A), where the shielding layer 190 is, for example, a black matrix layer. Then, in order to blur a pattern of a subsequently formed first sensing electrode layer 130 (referring to FIG. 2B), an optical layer 195 can be formed on the shielding layer 190 to cover the first sensing electrode layer 130, where the optical layer 195 is, for example, a low etching mark optical layer.

Then, referring to FIG. 1a and FIG. 2B, the first sensing electrode layer 130 is formed in the first central region (i.e. the sensing region 101 of FIG. 1A) of the first substrate 110, where a portion of the first sensing electrode layer 130 extends to the first periphery region (i.e. the periphery region 103 of FIG. 1A). Now, the optical layer 195 is located between the shielding layer 190 and the first sensing electrode layer 130. In detail, referring to FIG. 1A, the first sensing electrode layer 130 of the present embodiment is composed of a plurality of first sensing series 132 extending along a horizontal direction, where the first sensing series 132 are structures including a plurality of bridge lines L connecting a plurality of diamond touch pads P in series, and in other embodiments that are not illustrated, the shape of the touch pad can be a rectangle, a circle, a triangle or other shapes, and whether the bridge lines are used is not limited by the invention. Moreover, a material of the first sensing electrode layer 130 is, for example, ITO or IZO. And the step of forming the first sensing electrode layer 130 includes an exposure step, a developing step and an etching step. Here, a first mask (not shown) is used to fabricate the first sensing electrode layer 130.

Then, referring to FIG. 1A and FIG. 2C, a plurality of first lines 150 and a plurality of second lines 160 are formed in the first periphery region (i.e. the periphery region 103 of FIG. 1A) of the first substrate 110, where the first lines 150 are electrically insulated to each other, and the second lines 160 are electrically insulated to each other, and the first lines 150 are structurally and electrically connected to the first sensing electrode layer 130. Moreover, a material of the first lines 150 and the second lines 160 is, for example, metal, and the step of forming the first lines 150 and the second lines 160 includes an exposure step, a developing step and an etching step. Since the first lines 150 and the second lines 160 of the present embodiment are all disposed on the first substrate 110, the first lines 150 and the second lines 160 can be formed through a same mask process (i.e. a second mask, which is not illustrated).

Then, referring to FIG. 2D, an anisotropic conductive adhesive layer 185 is selectively formed on the second lines 160, which is used for improving electrical reliability between the second lines 160 and the subsequently adhered second sensing electrode layer 140 (referring to FIG. 2E). Certainly, the step of forming the anisotropic conductive adhesive layer 185 is selective, and the user can select to perform such step according to a requirement of the fabrication process, which is not limited by the invention.

Then, referring to FIG. 1B and FIG. 2E, a second substrate 120 is provided, where the second substrate 120 has a second central region (i.e. the sensing region 101 of FIG. 1B) and a second periphery region (i.e. the periphery region 103 of FIG. 1B) surrounding the second central region.

Then, referring to FIG. 1B and FIG. 2E, a second sensing electrode layer 140 is formed in the second central region (i.e. the sensing region 101 of FIG. 1B) of the second substrate 120, where a portion of the second sensing electrode layer 140 extends to the second periphery region (i.e. the periphery region 103 of FIG. 1B). In detail, referring to FIG. 1B, the second sensing electrode 140 of the present embodiment is composed of a plurality of second sensing series 142 extending along a vertical direction, where the second sensing series 142 are structures including a plurality of bridge lines L connecting a plurality of diamond touch pads P in series, and in other embodiments that are not illustrated, the shape of the touch pad can be a rectangle, a circle, a triangle or other shapes, and whether the bridge lines are used is not limited by the invention. Moreover, a material of the second sensing electrode layer 140 is, for example, ITO or IZO. And the step of forming the second sensing electrode layer 140 includes an exposure step, a developing step, an etching step and a printing step. Here, if the second sensing electrode layer 140 is formed through exposure, developing or etching, the second sensing electrode layer 140 is fabricated by using a third mask (not shown). If the second sensing electrode layer 140 is formed through printing (for example, screen printing), none mask is required.

Then, referring to FIG. 1B and FIG. 2F, an optical adhesive layer 170 is formed in the second central region (i.e. the sensing region 101 of FIG. 1B) and the second periphery region (i.e. the periphery region 103 of FIG. 1B) of the second substrate 120. The optical adhesive layer 170 covers the second sensing electrode layer 140 and has at least one opening 172 (two openings are schematically illustrated in FIG. 1B), where the opening 172 exposes a portion of the second sensing electrode layer 140.

Then, referring to FIG. 2G, a conductive material layer 180 is filled in the opening 172 of the optical adhesive layer 170, where the conductive material layer 180 is connected to the portion of second sensing electrode layer 140 exposed by the opening 172. Here, a material of the conductive material layer 180 is, for example, silver.

Finally, referring to FIG. 2H, an adhesion process is performed on the first substrate 110 and the second substrate 120 to fix the second substrate 120 to the first substrate 110 through the optical adhesive layer 170. The first sensing electrode layer 130 faces to the second sensing electrode layer 140, and the optical adhesive layer 170 encapsulates the first sensing electrode layer 130, the second sensing electrode layer 140, the first lines 150, the second lines 160 and the conductive material layer 180 due to the adhesion process, and fills a space between the optical layer 195 and the second substrate 120. Particularly, connection between the second lines 160 and the portion of second sensing electrode layer 140 exposed by the opening 172 through the conductive material layer 180 is implemented through a hot pressing process. Now, the shielding layer 190 is located above the first lines 150 and the second lines 160, which may effectively improve a light-shielding effect of the periphery region 103. In this way, fabrication of the touch panel 100 is completed.

It should be noticed that after the adhesion process, the first substrate 110 of the present embodiment can be regarded as an upper substrate, and the second substrate 120 is regarded as a lower substrate, where the first substrate 110 is a rigid substrate, which is, for example, a glass substrate, and the second substrate 120 is a flexible thin film, which is, for example, a polyethylene terephthalate (PET) thin film. Namely, the first sensing electrode layer 130, the first lines 150 and the second lines 160 of the present embodiment are all disposed on the rigid substrate (i.e. the upper substrate), and the second sensing electrode layer 140 is disposed on the flexible thin film (i.e. the lower substrate). However, configurations and materials of the first substrate 110 and the second substrate 120 are not limited by the invention, and in other embodiments that are not illustrated, the second substrate 120 can be regarded as the upper substrate, and the first substrate 110 can be regarded as the lower substrate, where the second substrate 120 is a rigid substrate, and the first substrate 110 is a flexible thin film. Namely, the first sensing electrode layer 130, the first lines 150 and the second lines 160 are all disposed on the flexible thin film (i.e. the lower substrate), and the second sensing electrode layer 140 is disposed on the rigid substrate (i.e. the upper substrate), which is also a technical solution without departing from a protection range of the invention.

Since the first lines 150 and the second lines 160 of the present embodiment are all formed on the first substrate 110 through a same photolithography process (i.e. an exposure process, a developing process and an etching process), compared to a manufacturing process of the conventional touch panel that four masks are used, in the manufacturing process of the touch panel 100 of the present embodiment, at least one mask process is saved, which may effectively reduce the production cost and achieve a higher production yield. Moreover, compared to the conventional printing method used for forming the metal lines, the manufacturing method (i.e. the exposure process, the developing process and the etching process) of the first lines 150 and the second lines 160 of the present embodiment may achieve smaller line width and pitch, so as to achieve a narrow line width effect of the touch panel 100. Moreover, if the printing process (for example, screen printing) is used to form the second sensing electrode layer 140, usage of a mask is unnecessary, which further saves another mask, i.e. two masks are saved compared to the conventional technique that four masks are used, which may effectively reduce the production cost and achieve a higher production yield.

FIG. 3 is a cross-sectional view of a touch display panel according to an embodiment of the invention. The touch display panel 10 includes the touch panel 100 shown in FIG. 1C (or FIG. 2H) and a display panel 200. The display panel 200 is disposed under the touch panel 100, and the display panel 200 is, for example, a liquid crystal display panel, an organic electro-luminescence display panel, an electronic paper display panel, an electrophoretic display panel, an electro-wetting display panel, a bi-stable type display panel, or a plasma display panel.

In summary, since the first lines and the second lines of the touch panel of the invention are all disposed on the first substrate, manufacturing of the first lines and the second lines can be completed through a same manufacturing process, which may effectively reduce the number of used masks to reduce the production cost and improve a production yield. Moreover, Since the first lines and the second lines are all formed on the first substrate through a photolithography process (i.e. an exposure process, a developing process and an etching process), compared to the conventional printing method used for forming the metal lines, the first lines and the second lines formed according to the method of the invention may have smaller line width and pitch, so as to achieve a narrow line width effect of the touch panel.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A touch panel, having a sensing region and a periphery region surrounding the sensing region, the touch panel comprising:
a first substrate;
a second substrate, disposed opposite to the first substrate;
a first sensing electrode layer, disposed on the first substrate and located in the sensing region, wherein a portion of the first sensing electrode layer extends to the periphery region;
a second sensing electrode layer, disposed on the second substrate and facing to the first sensing electrode layer, and located in the sensing region, wherein a portion of the second sensing electrode layer extends to the periphery region;
a plurality of first lines, disposed on the first substrate and located in the peripheral region, wherein the first lines are electrically insulated to each other, and are connected to the first sensing electrode layer;
a plurality of second lines, disposed on the first substrate and located in the peripheral region, wherein the second lines are electrically insulated to each other;
an optical adhesive layer, disposed between the first substrate and the second substrate, and encapsulating the first sensing electrode layer, the second sensing electrode layer, the first lines and the second lines, wherein the optical adhesive layer has at least one opening exposing the portion of the second sensing electrode layer extending to the periphery region;
a conductive material layer, disposed inside the opening of the optical adhesive layer, wherein the second lines are connected to the second sensing electrode layer through the conductive material layer; and
a shielding layer, disposed between the first substrate and the second substrate, and located in the periphery region above the first lines and the second lines.

2. The touch panel as claimed in claim 1, wherein at least one of the first substrate and the second substrate is a rigid substrate.

3. The touch panel as claimed in claim 2, wherein at least one of the first substrate and the second substrate is a flexible thin film.

4. The touch panel as claimed in claim 1, further comprising an optical layer disposed on the shielding layer and located between the first substrate and the first sensing electrode layer or between the second substrate and the second sensing electrode layer.

5. The touch panel as claimed in claim 1, further comprising an anisotropic conductive adhesive layer disposed on the second lines, wherein the second lines are connected to the second sensing electrode layer through the conductive material layer and the anisotropic conductive adhesive layer.

6. The touch panel as claimed in claim 1, wherein a material of the first sensing electrode layer and the second sensing electrode layer comprises indium tin oxide (ITO) or indium zinc oxide (IZO).

7. The touch panel as claimed in claim 1, wherein a material of the conductive material layer comprises silver.

8. A manufacturing method of a touch panel, comprising:
providing a first substrate, wherein the first substrate has a first central region and a first periphery region surrounding the first central region;
forming a first sensing electrode layer in the first central region of the first substrate, wherein a portion of the first sensing electrode layer extends to the first periphery region;
forming a plurality of first lines and a plurality of second lines in the first periphery region of the first substrate, wherein the first lines are electrically insulated to each other, the second lines are electrically insulated to each other, and the first lines are connected to the first sensing electrode layer;
providing a second substrate, wherein the second substrate has a second central region and a second periphery region surrounding the second central region;
forming a second sensing electrode layer in the second central region of the second substrate, wherein a portion of the second sensing electrode layer extends to the second periphery region;
forming an optical adhesive layer in the second central region and the second periphery region of the second substrate, the optical adhesive layer covering the second sensing electrode layer and have at least one opening, wherein the opening exposes the portion of the second sensing electrode layer;
filling a conductive material layer in the opening of the optical adhesive layer, wherein the conductive material layer is connected to the portion of second sensing electrode layer exposed by the opening;
performing an adhesion process on the first substrate and the second substrate to fix the second substrate to the first substrate through the optical adhesive layer, wherein the first sensing electrode layer faces to the second sensing electrode layer, and the optical adhesive layer encapsulates the first sensing electrode layer, the second sensing electrode layer, the first lines, the second lines and the conductive material layer, and the second lines are connected to the portion of second sensing electrode layer exposed by the opening through the conductive material layer; and
before the adhesion process is performed, forming a shielding layer in the first periphery region of the first substrate or in the second periphery region of the second substrate, wherein the shielding layer is located above the first and the second lines.

9. The manufacturing method of the touch panel as claimed in claim 8, further comprising:
forming an optical layer on the shielding layer after the shielding layer is formed and before the first sensing electrode layer or the second sensing electrode layer is formed, wherein the optical layer is located between the first substrate and the first sensing electrode layer or between the second substrate and the second sensing electrode layer.

10. The manufacturing method of the touch panel as claimed in claim 8, further comprising:
forming an anisotropic conductive adhesive layer on the second lines after the second lines are formed.

11. The manufacturing method of the touch panel as claimed in claim 8, wherein the step of forming the first sensing electrode layer comprises an exposure step, a developing step and an etching step.

12. The manufacturing method of the touch panel as claimed in claim 8, wherein the step of forming the second sensing electrode layer comprises an exposure step, a developing step, and an etching step or a printing step.

13. The manufacturing method of the touch panel as claimed in claim 8, wherein the step of forming the first lines and the second lines comprises an exposure step, a developing step and an etching step.

14. A touch display panel, comprising:
a touch panel, having a sensing region and a periphery region surrounding the sensing region, and comprising:
a first substrate;
a second substrate, disposed opposite to the first substrate;
a first sensing electrode layer, disposed on the first substrate and located in the sensing region, wherein a portion of the first sensing electrode layer extends to the periphery region;
a second sensing electrode layer, disposed on the second substrate and facing to the first sensing electrode layer, the second sensing electrode layer being located in the sensing region, wherein a portion of the second sensing electrode layer extends to the periphery region;
a plurality of first lines, disposed on the first substrate and located in the peripheral region, wherein the first lines are electrically insulated to each other, and are connected to the first sensing electrode layer;
a plurality of second lines, disposed on the first substrate and located in the peripheral region, wherein the second lines are electrically insulated to each other;
an optical adhesive layer, disposed between the first substrate and the second substrate, and encapsulating the first sensing electrode layer, the second sensing electrode layer, the first lines and the second lines, wherein the optical adhesive layer has at least one opening exposing the portion of the second sensing electrode layer extending to the periphery region;
a conductive material layer, disposed inside the opening of the optical adhesive layer, wherein the second lines are connected to the second sensing electrode layer through the conductive material layer; and
a shielding layer, disposed between the first substrate and the second substrate, and located in the periphery region above the first and the second lines; and
a display panel, disposed under the touch panel.

15. The touch display panel as claimed in claim 14, wherein at least one of the first substrate and the second substrate is a rigid substrate.

16. The touch display panel as claimed in claim 15, wherein at least one of the first substrate and the second substrate is a flexible thin film.

17. The touch display panel as claimed in claim 14, further comprising an optical layer disposed on the shielding layer and located between the first substrate and the first sensing electrode layer or between the second substrate and the second sensing electrode layer.

18. The touch display panel as claimed in claim 14, further comprising an anisotropic conductive adhesive layer disposed on the second lines, wherein the second lines are connected to the second sensing electrode layer through the conductive material layer and the anisotropic conductive adhesive layer.

19. The touch display panel as claimed in claim 14, wherein a material of the first sensing electrode layer and the second sensing electrode layer comprises indium tin oxide (ITO) or indium zinc oxide (IZO).

20. The touch display panel as claimed in claim 14, wherein a material of the conductive material layer comprises silver.
